(19) United States
(12) Patent Application Publication
(10) Pub. No.: US 2009/0218667 A1
(43) Pub. Date: Sep. 3, 2009

(54) SMART CARDS AND METHODS FOR PRODUCING A SMART CARD

(76) Inventors: Frank Pueschner, Kelheim (DE); Detlef Houdeau, Langquaid (DE); Andreas Mehlhaff, Landshut (DE); Peter Stampka, Burglengenfeld (DE)

Correspondence Address: INFINEON TECHNOLOGIES AG;Patent Department, MUC 11.1.507, P.O. Box 221644, Munich, 80506, DE

(21) Appl. No.: 12/392,112

(22) Filed: Feb. 25, 2009

(30) Foreign Application Priority Data
Feb. 28, 2008 (DE) 102008011611.4

(51) Int. Cl. H01L 23/00; B32B 27/28; B32B 37/00; B32B 38/00; H01L 21/50

(52) U.S. Cl. 257/679; 428/412; 428/339; 156/60; 156/244.11; 438/125; 257/E23.002; 257/E21.499

(57) ABSTRACT

The invention relates to smart cards. In one embodiment a smart card has a card body having at least a first, a second and a third layer. The first and the second layer are at least partly composed of polycarbonate. The third layer is arranged between the first and the second layer and is composed of a material having a melting point of Tₛ<150° C.

### FOREIGN PRIORITY

This application claims priority to German Patent Application. No. 102008011611, filed Feb. 28, 2008, which is incorporated herein by reference in its entirety.

### BACKGROUND

Smart cards are finding more and more applications worldwide. Thus, smart cards have for example already long been known as storage cards for telephone applications.

With increasing computing power and storage capacity of the semiconductor chips, however, smart cards are finding diverse further uses, such as, for example, as a card for those with health insurance, or as an identity card.

Contactless smart cards, in particular, in which power and data are transmitted without direct electrical coupling between card and terminal, are increasingly being used.

The materials, the construction and the production of the card body are essentially determined by functional elements of the cards and by the loading of the card in the course of handling during the application.

For applications in which high strength and longevity are required, polycarbonate (PC) is often used at the present time. It is a typical material for identity cards, but has a high stress corrosion cracking sensitivity.

### SUMMARY

Embodiments are related to smart cards comprising a card body which is at least partly composed of polycarbonate, and to a method for producing such a smart card.

One embodiment relates to a smart card comprising a card body, wherein the card body has at least a first, a second and a third layer. The first and the second layer are at least partly composed of polycarbonate. The third layer is arranged between the first and the second layer and is composed of a material having a melting point Tₛ<150° C.

In one embodiment, a method for producing a card body for a smart card comprises constructing the card body from at least a first, a second and a third layer. The first and the second layer are at least partly produced from polycarbonate. The third layer is arranged between the first and the second layer and produced from a material having a melting point of Tₛ<150° C.

### BRIEF DESCRIPTION OF THE DRAWINGS

The invention may be more completely understood from the following detailed description of various embodiments in connection with the accompanying drawings, in which:

FIG. 1 shows a schematic cross-sectional view of an embodiment of a partial excerpt from a smart card body.

FIG. 2 shows a schematic cross-sectional view of an embodiment of a smart card with a smart card body and a semiconductor chip.

FIG. 3 shows a schematic cross-sectional view of an embodiment of a smart card with a smart card body and a semiconductor module.

FIG. 4 shows a schematic cross-sectional view of an edge region of a chip module for a smart card.

FIG. 5 shows a schematic cross-sectional view of an exemplary embodiment of a prefabricated film for a smart card body.

Identical elements in the figures are provided with the same or similar reference symbols, and that a repeated description of these elements is omitted.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

FIG. 1 illustrates a partial excerpt from a smart card body in cross section. The smart card body comprises at least a first layer 11 and a second layer 12, which are at least partly composed of polycarbonate. Arranged between the two polycarbonate layers 11 and 12 is a third layer 13, which is composed of a material having a melting point of Tₛ<150° C. In one embodiment a smart card comprising a card body which contains polycarbonate may have a lower stress corrosion cracking sensitivity than a conventional card body comprising polycarbonate.

By virtue of the arrangement of such a third layer 13 having a low melting point in comparison with polycarbonate, polycarbonate layers can be combined with the aid of this interlayer 13 with lower temperature loadings than if the polycarbonate layers have to be directly connected to one another. By virtue of the lower melting point of the third layer 13, the polycarbonate layers 11 and 12 can be combined with the third layer 13 for example at lower temperatures by means of laminating technology. The third layer 13 thus constitutes an adhesion layer between two polycarbonate layers. By virtue of the lower temperature loading during the production of the card body, inherent stresses possibly occurring in the polycarbonate layer around a foreign body in the polycarbonate layer will correspondingly also turn out to be lower. Moreover, inherent stress cracks that normally propagate in polycarbonate on account of stress corrosion cracking are stopped at said third layer 13. The card body therefore has a lower notch sensitivity.

The arrangement of the third layer between the two polycarbonate layers significantly reduces the notch sensitivity of the card body. The use of the interlayer having a low melting point enables a card body production process with low temperatures. Inherent stresses brought about by temperature loadings can thus be reduced. The interlayer can additionally serve as a stop layer for microcracks in the polycarbonate layers.

Appropriate material for the third layer 13 includes for example a material at least from one of the groups of polyethylene terephthalate (PET), such as e.g. amorphous PET (APET), PET with glycol (PET-G), PET with fluorine (PET-F), and polyvinyl chloride (PVC).

The third layer 13 can have a thickness within the range of 3 μm to 10 μm. In possible embodiments, at least one of the polycarbonate layers 11 or 12 can be optically transparent. In exemplary embodiments, the third layer 13 can have one or a combination of the states amorphous, uncolored and transparent. However, it can also have one or a combination of the states partly crystalline, uncolored and translucent. Furthermore, the third layer can also be colored, e.g. in order to increase the contrast on the overlying layer.

The third layer 13 can additionally serve as a carrier for optical security features such as, for example, a hologram, a kinegram, a microtext, a micro-coding (barcode), one or a plurality of reflection layers (e.g. in displays) and/or a carrier for electronic security features (e.g. a structured metal film in the form of a security thread or in the form of a closed antenna).

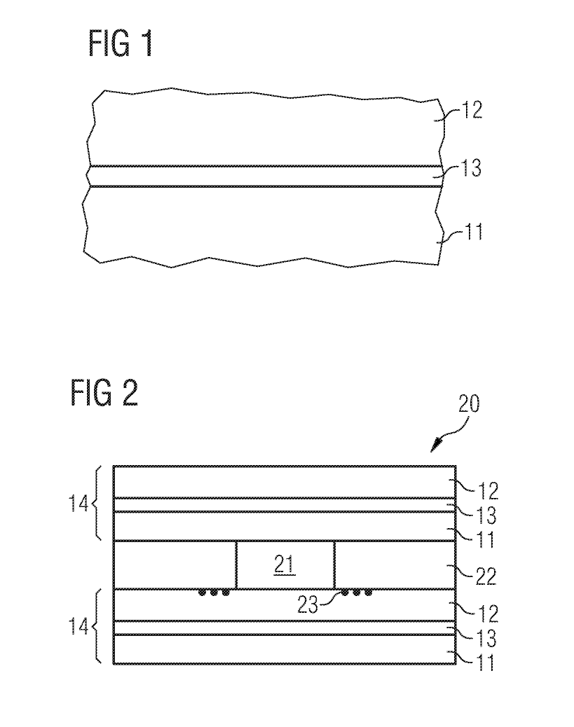

FIG. 2 illustrates an exemplary embodiment of a smart card 20. The smart card 20 has a card body composed of two layer stacks 14 and an intermediate film 22 between the two layer stacks 14. In this case, as already explained with regard to FIG. 1, the layer stack 14 is composed of two polycarbonate layers 11 and 12 and a third layer 13 lying in between.

The intermediate film 22 arranged between the two layer stacks 14 can likewise be at least partly composed of polycarbonate. In the exemplary embodiment shown, the intermediate film 22 has an interruption in which a semiconductor chip 21, for example a microcontroller, is likewise arranged between the two layer stacks 14. The semiconductor chip 21 is thus arranged in the card body and is completely enveloped by the card body in the example shown.

FIG. 2 additionally illustrates an antenna 23, which is arranged in the semiconductor body. The antenna can be introduced for example in a polycarbonate layer of the layer stack 14. The embodiment shown in FIG. 2 provides a coil antenna, above the coil eye of which the semiconductor chip 21 is arranged. The semiconductor chip 21 will generally be connected to the antenna 23 in order to enable power and/or data transmission with external terminals.

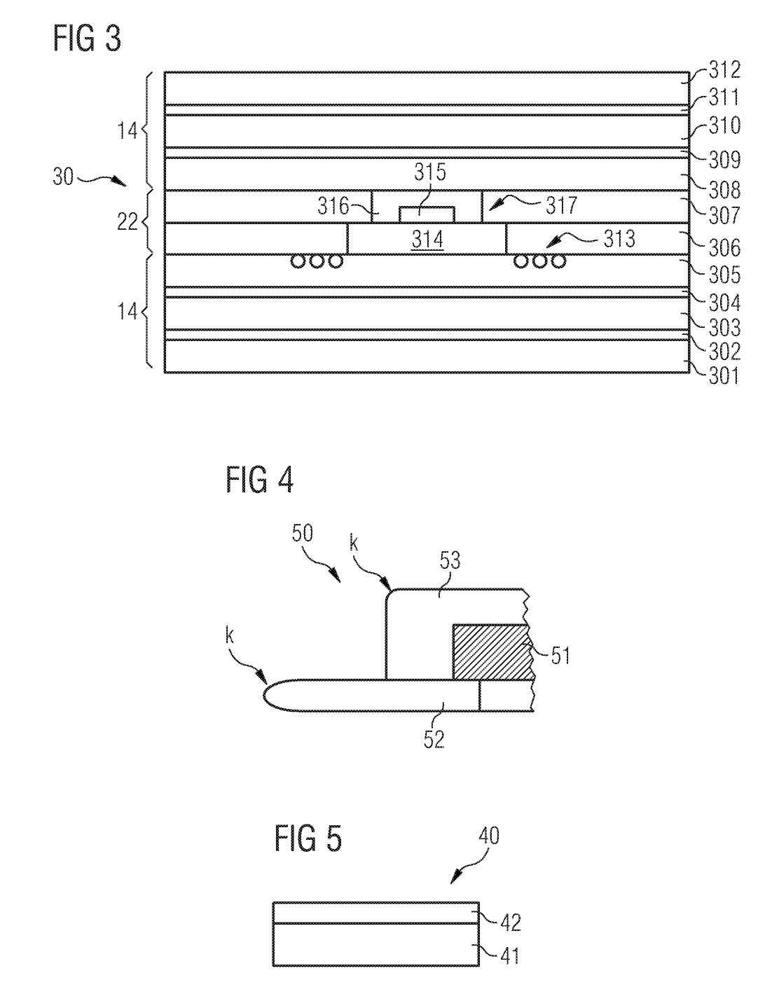

FIG. 3 shows a further exemplary embodiment of a smart card 30 comprising a smart card body and a semiconductor module. The smart card body of this exemplary embodiment is likewise composed of two layer stacks 14 and an intermediate film 22 arranged between the two layer stacks 14. In FIG. 3, a layer stack 14 has three polycarbonate layers 301, 303, 305 and 308, 310, 312 with in each case third layers 302, 304 and 309 and 311, respectively, arranged between two polycarbonate layers. By virtue of this arrangement, as already explained with regard to FIG. 1, the card body can be made less notch-sensitive on account of lower temperature loading during the laminating process during the production of the layer stack 14 and by means of the stop function of the third layers for microcracks.

As illustrated in FIG. 3, the intermediate film 22 can be composed of a plurality of individual layers 306, 307. This enables for example the dimensionally accurate adaptation of the intermediate film 22 to a semiconductor chip or, as illustrated in FIG. 3, to a semiconductor chip module 317.

The semiconductor chip module 317 comprises for example a chip carrier 314, a semiconductor chip 315 and a housing 316 for the semiconductor chip 315. The semiconductor chip module 317 is arranged in an interruption of the intermediate film 22 between the two layer stacks 14. Consequently, the semiconductor chip module 317 is likewise arranged in the semiconductor body and is completely enveloped by the semiconductor body.

In the exemplary embodiment illustrated in FIG. 3, an antenna 313 is arranged in the semiconductor body. As already explained in FIG. 2, the antenna can be a coil antenna, for example, which is incorporated in a polycarbonate layer. The semiconductor chip module 317 is situated above the coil eye between the coil strands of the antenna and is generally connected to the two ends of the coil antenna in order to enable the power and data exchange between the semiconductor chip 315 and an external terminal.

FIG. 4 shows a possible embodiment of a semiconductor chip module. The illustrated edge region of a semiconductor chip module 50 comprises a semiconductor chip carrier 52, e.g. a leadframe, a semiconductor chip 51 on the chip carrier 52 and a housing 53 for the semiconductor chip 51. The edges K of this exemplary semiconductor chip module 50 are rounded in this case. This embodiment alleviates critical locations for stress cracking in the polycarbonate layers surrounding the semiconductor chip module 50 because the notch effect in the polycarbonate layers is reduced by the rounded edges. In this case, the edge rounding has an edge radius r where
r≦0.1 mm.

FIG. 5 shows a composite film 40 that can be used for a production variant of the card body of a smart card according to the invention. The composite film 40 is composed of a first layer 41, which is at least partly composed of polycarbonate, and a third layer 42, which is composed of a material having a melting point of Tₛ<150° C. The composite film can be used as a prefabricated product for the production of the card body of the smart cards described above.

The composite film 40 can be produced in such a way that the third layer 42 is laminated onto the first layer 41. A further possibility for producing the composite film 40 consists in the first layer 41 and the third layer 42 being coextruded, that is to say that the materials of the first layer 41 and of the third layer 42 are brought together before leaving a profile die and a composite film as illustrated in FIG. 5 thus emerges from the profile die.

1. A smart card comprising a card body, wherein the card body has at least a first, a second and a third layer, wherein the first and the second layer are at least partly composed of polycarbonate and wherein the third layer is arranged between the first and the second layer and is composed of a material having a melting point of Tₛ<150° C.

2. The smart card of claim 1, wherein the third layer has a thickness within the range of 3 μm to 10 μm.

3. The smart card of claim 1, wherein the material of the third layer is taken at least from a group of the materials PET, PVC, APET, PET-G, PET-F.

4. The smart card as of claim 1, wherein a semiconductor chip is arranged in the card body.

5. The smart card as claimed in claim 4, wherein the semiconductor chip is completely enveloped by the card body.

6. The smart card of claim 1, wherein an antenna is arranged in the card body.

7. The smart card of claim 4, wherein the semiconductor chip is part of a semiconductor module, wherein the semiconductor module has a carrier for the semiconductor chip and a housing for the semiconductor chip.

8. The smart card of claim 7, wherein the semiconductor module has rounded edges.

9. The smart card of claim 8, wherein the edges have an edge radius r≧0.1 mm.

10. The smart card of claim 1, wherein at least the first or the second layer is optically transparent.

11. The smart card of claim 10, wherein the third layer is a carrier for optical security features.

12. The smart card of claim 10, wherein the third layer is optically transparent at least in partial regions.

13. The smart card of claim 12, wherein the third layer is a carrier for optical security features.

14. The smart card of claim 1, wherein the third layer is a carrier of electronic security features.

15. A method for producing a card body for a smart card comprising constructing the card body from at least a first, a second and a third layer, wherein the first and the second layer are at least partly produced from polycarbonate and the third layer is produced from a material having a melting point of Tₛ<150° C. and is arranged between the first and the second layer.

16. The method of claim 15, wherein at least the second layer is laminated onto the third layer.

17. The method of claim 15, wherein the first and the third layer are provided as a composite film.

18. The method of claim 15, wherein the third layer is laminated onto the first layer.

19. The method of claim 15, wherein the first layer and the third layer are coextruded.

20. The method of claim 15, wherein a semiconductor chip is introduced into the card body.

21. The method as claimed in claim 20, wherein the semiconductor chip is completely introduced into the card body, such that the card body completely envelopes the semiconductor chip.

22. A method for producing a smart card comprising producing a layer stack at two opposite sides of a semiconductor chip, wherein the layer stack has at least a first layer, a second layer and a third layer, and wherein the first and the second layer are at least partly produced from polycarbonate and the third layer composed of a material having a melting point of Tₛ<150° C. is arranged between the first and the second layer.
